(19) United States
(12) Patent Application Publication
(10) Pub. No.: US 2005/0205981 A1
(43) Pub. Date: Sep. 22, 2005

(54) Stacked electronic part

(75) Inventors: Atsushi Yoshimura, Yokosuka-shi (JP); Tadanobu Ookubo, Yokkaichi-shi (JP); Yoshiaki Sugizaki, Oita-shi (JP); Susumu Harada, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/081,596

(22) Filed: Mar. 17, 2005

(30) Foreign Application Priority Data
Mar. 18, 2004 (JP) P2004-078333
Mar. 18, 2004 (JP) P2004-078334

(51) Int. Cl. H01L 23/02

(52) U.S. Cl. 257/686

(57) ABSTRACT

A stacked electronic part comprises a first electronic part which is adhered onto a circuit board via a first adhesive layer and a second electronic part which is adhered onto the first electronic part via a second adhesive layer. An insulating resin having a filling viscosity of 1 Pa·s or more and less than 1000 Pa·s or a photo-setting insulating resin is filled in the spaces below first bonding wires which are connected to the first electronic part. Thus, the occurrence of bubbles resulting from the resin non-filled portions below the wires can be prevented. Besides, the first electronic part and the second electronic part are adhered via an insulating resin layer having an adhering viscosity of 1 kPa·s or more and 100 kPa·s or less. Therefore, the occurrence of an insulation failure, a short circuit or the like resulting from a contact between the bonding wires of the lower electronic part and the upper electronic part can be prevented.

### CROSSREFERENCE TO RELATED APPLICATIONS

This application is based upon and claims the benefit of priority from the prior Japanese Patent Applications No. 2004-078333 and No. 2004-078334, filed on Mar. 18, 2004; the entire contents of which are incorporated herein by reference.

### BACKGROUND

1. Field of the Invention

The present invention relates to a stacked electronic part configured by stacking plural electronic parts.

2. Description of the Related Art

In recent years, to realize miniaturization, high-density packaging and the like of the semiconductor device, there is realized a stacked multichip package which has plural semiconductor elements (semiconductor chips) stacked and sealed in a single package. The stacked multichip package has the plural semiconductor elements sequentially stacked on a circuit board with an adhesive agent such as a die attach material interposed. Electrode pads of each semiconductor element are electrically connected to electrode portions of the circuit board via bonding wires. And, this stacked structure is packaged with a sealing resin to configure a stacked multichip package.

In the above-described stacked multichip package, when the upper semiconductor element is smaller than the lower semiconductor element, the upper semiconductor element does not interfere with the bonding wires of the lower semiconductor element. In such a structure, however, the semiconductor elements applicable are considerably limited, so that the expansion of the applicability to the semiconductor elements having the same shape and the semiconductor elements that the upper one is larger than the lower one is being conducted. Here, where the semiconductor elements having the same shape are stacked or the lower semiconductor element and the larger upper one are stacked, there is a possibility that the bonding wires of the lower semiconductor element come into contact with the upper semiconductor element. Therefore, it is important to prevent the occurrence of an insulation failure, a short circuit or the like due to a contact of the bonding wires.

Accordingly, a spacer, which is set to have a thickness so that the under surface of the upper semiconductor element becomes higher than the heights of the bonding wires connected to the lower semiconductor element, is disposed between the upper and lower semiconductor elements (e.g., Japanese Patent Laid-Open Applications No. 2003-179200 and No. 2003-218316). When the spacer is disposed between the semiconductor elements, it is necessary to arrange the bonding wires in the space formed by the spacer and to seal the space in which the bonding wires are disposed with an adhesive resin or the like. At that time, if an amount of the resin filled in the space where the bonding wires are arranged is insufficient, there is a problem that a resin non-filled portion is apt to occur below the wires.

It is also practiced to form the space for preventing the contact of the bonding wires between the semiconductor elements without using the spacer. For example, Japanese Patent Laid-Open Application No. 2004-072009 describes a semiconductor device that an insulating adhesive agent layer for adhering the semiconductor elements has a thickness larger than the heights of the bonding wires. The bonding wires are partly arranged in the insulating adhesive agent layer. Japanese Patent Laid-Open Application No. HEI 08-288455 describes a structure that the insulating resin layer and the fixing resin layer are sequentially formed on the lower semiconductor element, and the upper semiconductor element is arranged and fixed. Besides, Japanese Patent Laid-Open Application No. 2004-193363 describes that the back surface of the upper semiconductor element is electrically insulated to prevent an insulation failure, a short circuit or the like resulting from the contact between the bonding wires and the semiconductor element.

As described above, the semiconductor device having a structure that the spacer is arranged between the semiconductor elements has a problem that the resin non-filled portion is apt to occur in the spaces below the bonding wires. It is also difficult to fill the resin in the resin non-filled portions below the wires in the subsequent resin molding step, so that bubbles resulting from the resin non-filled portions remain. When bubbles generate in the semiconductor device, separation, leakage or the like is apt to occur resulting from the bubbles in a reliability test on moisture absorption, solder reflow or the like, and the reliability of the semiconductor device is impaired. To prevent the generation of the resin non-filled portions, there are considered the use of an adhesive agent resin having a low viscosity or an increase of a filling amount of the adhesive agent resin. But, such a case involves a problem such as oozing out (bleed) of the resin from the element end surface, creeping upward of the resin or the like.

Meanwhile, in the structure (a spacer-omitted structure) that the space between the semiconductor elements is kept by the adhesive agent layer, it is necessary to use an adhesive agent resin having a high viscosity to keep the shape of the adhesive agent layer. Thus, when the adhesive agent resin having a high viscosity is used, the above-described resin non-filled portions below the wires become more susceptible to generation. Especially, in a semiconductor device that plural semiconductor elements are stacked without using the spacer, the adhesive agent layer serves as the spacer and also as the sealing resin, so that it is hard to keep the shape and to improve the filling property at the same time.

Thus, the semiconductor device applying the conventional stacked multichip package structure has a problem that the resin non-filled portions tend to generate below the bonding wires and remain as bubbles, resulting in decreasing the reliability of the semiconductor device. Especially, the semiconductor device not using the spacer is hard to improve the filling property of the adhesive agent resin while keeping the shape of the layer for preventing the contact of the bonding wires. Such a problem is not limited to the semiconductor device which has the plural semiconductor elements stacked but also occurs in a stacked electronic part which has various types of electronic parts stacked and packaged.

### SUMMARY

Accordingly, according to an aspect of the present invention, there is provided a stacked electronic part that the generation of bubbles resulting from resin non-filled portions below bonding wires is retarded and the space for prevention of the generation of an insulation failure, a short circuit or the like resulting from the contact between bonding wires of a lower electronic part and an upper electronic part can be kept.

A stacked electronic part according to an embodiment of the present invention comprises a substrate having electrode portions; a first electronic part having first electrode pads which are connected to the electrode portions via first bonding wires and bonded on the substrate via a first adhesive layer; and a second electronic part having second electrode pads which are connected to the electrode portions via second bonding wires and bonded on the first electronic part via a second adhesive layer; wherein the second adhesive layer has a first insulating resin, which is filled in the spaces between the first electronic part and the first bonding wires, and a second insulating resin, which is disposed to adhere the first electronic part and the second electronic part and has a modulus of elasticity different from that of the first insulating resin.

A stacked electronic part according to an embodiment of the present invention comprises a substrate having electrode portions; a first electronic part having first electrode pads which are connected to the electrode portions via first bonding wires and bonded on the substrate via a first adhesive layer; and a second electronic part having second electrode pads which are connected to the electrode portions via second bonding wires and bonded on the first electronic part via a second adhesive layer; wherein the second adhesive layer has a first insulating resin, which is filled in the spaces between the first electronic part and the first bonding wires and has a filling viscosity of in a range 1 Pa·s or more and less than 1000 Pa·s, and a second insulating resin, which is disposed to adhere the first electronic part and the second electronic part and has an adhering viscosity in a range of 1 kPa·s or more and 100 kPa·s or less.

A stacked electronic part according to still another embodiment of the present invention comprises a substrate having electrode portions; a first electronic part having first electrode pads which are connected to the electrode portions via first bonding wires and bonded on the substrate via a first adhesive layer; and a second electronic part having second electrode pads which are connected to the electrode portions via second bonding wires and bonded on the first electronic part via a second adhesive layer; wherein the second adhesive layer has a photo-setting insulating resin, which is filled in the spaces between the first electronic part and the first bonding wires, and a thermosetting insulating resin, which is disposed to adhere the first electronic part and the second electronic part and has an adhering viscosity in a range of 1 kPa·s or more and 100 kPa·s or less.

### BRIEF DESCRIPTION OF THE DRAWINGS

The present invention is described with reference to the drawings, which are provided for illustration only and do not limit the present invention in any respect.

FIG. 1 is a sectional view schematically showing a structure of a first embodiment applying the stacked electronic part of the present invention to a semiconductor device.

FIG. 2 is an enlarged sectional view showing a main portion of the semiconductor device shown in FIG. 1.

FIG. 3 is a plan view showing one structure example of a mode of filling a first insulating resin of the semiconductor device shown in FIG. 1.

FIG. 4 is a plan view showing another structure example of the mode of filling the first insulating resin of the semiconductor device shown in FIG. 1.

FIG. 5 is a view showing an example of viscosity characteristic of an insulating resin (adhesive agent resin) applicable to the semiconductor device according to an embodiment of the present invention.

FIG. 6 is a sectional view showing a modified example of the semiconductor device shown in FIG. 1.

FIG. 7 is an enlarged sectional view showing a main portion of the semiconductor device shown in FIG. 6.

FIG. 8 is an enlarged sectional view of a main portion of a semiconductor device shown for comparison with FIG. 7.

FIG. 9 is a sectional view showing a step of manufacturing the main portion of the semiconductor device shown in FIG. 7.

FIG. 10 is a sectional view showing another modified example of the semiconductor device shown in FIG. 1.

FIG. 11 is a sectional view showing still another modified example of the semiconductor device shown in FIG. 1.

FIG. 12 is a sectional view schematically showing a structure of a second embodiment applying the stacked electronic part of the present invention to a semiconductor device.

FIG. 13 is a plan view showing one structure example of a filling and curing mode of a photo-setting insulating resin of the semiconductor device shown in FIG. 12.

FIG. 14 is a sectional view schematically showing a structure of a third embodiment applying the stacked electronic part of the present invention to a semiconductor device.

FIG. 15 is a sectional view showing one modified example of the semiconductor device shown in FIG. 14.

FIG. 16 is a sectional view showing another modified example of the semiconductor device shown in FIG. 14.

### DETAILED DESCRIPTION

Modes of conducting the present invention will be described with reference to the drawings. Embodiments of the present invention are described with reference to the drawings, which are provided for illustration only, and the present invention is not limited to the drawings.

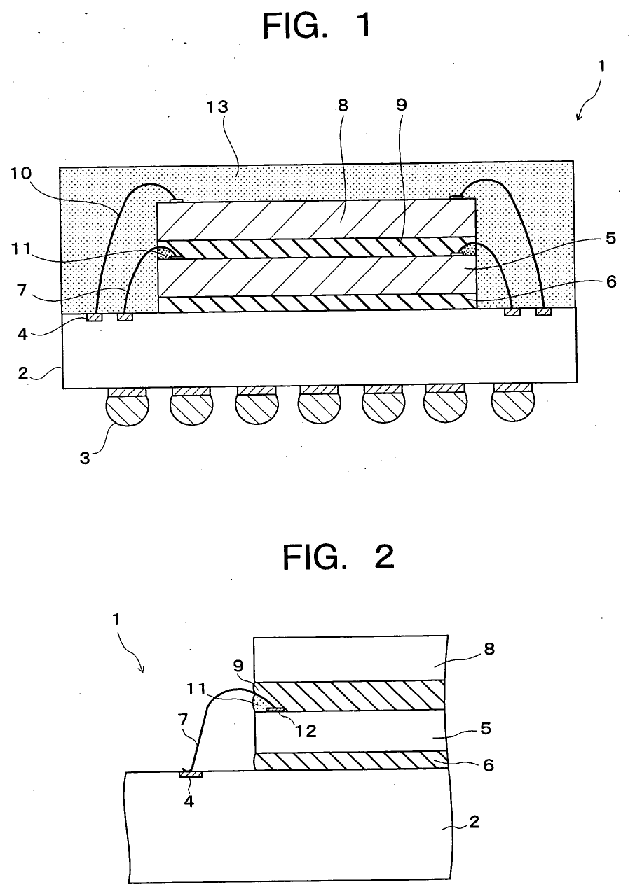

FIG. 1 is a sectional view schematically showing a structure of a first embodiment applying the stacked electronic part of the present invention to a semiconductor device having a stacked multichip configuration. A semiconductor device 1 shown in the drawing has a substrate 2 for mounting elements. The substrate 2 for mounting elements can mount electronic parts, and has a circuit. For the substrate 2, a circuit board in which a circuit is formed to a surface or a inside of an insulating substrate or a semiconductor substrate, or a substrate which integrated a mounting part and a circuit like a leadframe can be applied. The semiconductor device 1 has a circuit board 2 as a substrate for mounting elements. For the circuit board 2, the substrates formed of various types of materials, such as a resin substrate, a ceramic substrate, a glass substrate, a semiconductor substrate and the like, can be applied. As the resin substrate, a general multilayer copper-clad laminated plate (multilayer printed circuit board) or the like is used. External connection terminals 3 such as solder bumps are formed on the bottom surface of the circuit board 2.

On the top surface, on which the elements of the circuit board 2 are mounted, electrode portions 4 which are electrically connected to the external connection terminals 3 via, for example, inner layer wires (not shown) are disposed. The electrode portions 4 become wire bonding portions. On the element mounting surface (top surface) of the circuit board 2, a first semiconductor element 5 is adhered as a first electronic part via a first adhesive layer 6. For the first adhesive layer 6, a general die attach material (die attach film or the like) is used. First electrode pads (not shown) disposed on the top surface of the first semiconductor element 5 are electrically connected to the electrode portions 4 of the circuit board 2 via first bonding wires 7.

Besides, a second semiconductor element 8 is adhered as a second electronic part on the first semiconductor element 5 via a second adhesive layer 9. The second semiconductor element 8 has a shape equal to or larger than that of the first semiconductor element 5. Second electrode pads (not shown) disposed on the top surface of the second semiconductor element 8 are electrically connected to the electrode portions 4 of the circuit board 2 via second bonding wires 10.

A first insulating resin 11 having a filling viscosity in a range of 1 Pa·s or more and less than 1000 Pa·s is filled in the spaces between the first semiconductor element 5 and the first bonding wires 7 as shown in the enlarged view of FIG. 2. Reference numeral 12 denotes first electrode pads which are disposed on the top surface of the first semiconductor element 5. The second adhesive layer 9 is formed of a second insulating resin (adhesive agent resin) having an adhering viscosity of 1 kPa·s or more and 100 kPa·s or less excepting the portions filled with the first insulating resin 11. In other words, the first semiconductor element 5 and the second semiconductor element 8 are mutually adhered via the second adhesive layer 9 which is mainly formed of the second insulating resin.

The first insulating resin 11 is filled in the spaces between the first semiconductor element 5 and the first bonding wires 7 after the first bonding wires 7 are bonded to the electrode pads of the first semiconductor element 5 and before the step of adhering the second semiconductor element 8. Thus, by previously filling the first insulating resin 11 in the spaces between the first semiconductor element 5 and the first bonding wires 7, the occurrence of bubbles or the like from resin non-filled portions below the wires can be prevented without fail.

Besides, it is not necessary to worry the occurrence of a resin non-filled portion below the wires, so that an adhesive agent resin having a high viscosity capable of keeping its shape (prescribed layer thickness or the like) can be applied to the second insulating resin which mainly configures the second adhesive layer 9. Thus, a function of holding the space between the first and second semiconductor elements 5 and 8 can be given to the second adhesive layer (second insulating resin layer) 9. By using the second adhesive layer 9 which is mainly formed of the second insulating resin having such a high viscosity, the occurrence of an insulation failure, a short circuit or the like resulting from contact between the first bonding wires 7 and the second semiconductor element 8 can be suppressed with a good reproducibility.

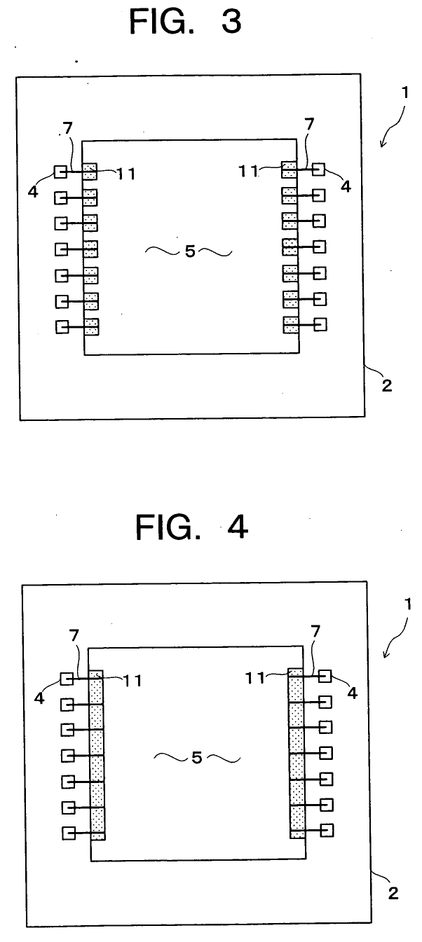

The first insulating resin 11 is filled in each space between the first semiconductor element 5 and the first bonding wires 7 as shown in, for example, FIG. 3. The first insulating resin 11 shown in FIG. 3 can be filled in the individual spaces between the first semiconductor element 5 and the first bonding wires 7 by sequentially potting, for example, an insulating resin paste. This structure of filling the first insulating resin 11 has advantages that it is effective when the first bonding wires 7 have a relatively large forming pitch and the volume of the second adhesive layer 9 can be calculated easily.

As shown in FIG. 4, the first insulating resin 11 may be filled to connect all the spaces between the first semiconductor element 5 and the first bonding wires 7. The first insulating resin 11 shown in FIG. 4 can be filled in all the spaces between the first semiconductor element 5 and the first bonding wires 7 by, for example, screen printing an insulating resin paste. This structure of filling the first insulating resin 11 is effective when the first bonding wires 7 have a relatively narrow forming pitch and also effective in preventing the first bonding wires 7 from deforming.

The first insulating resin 11 is filled in the spaces between the first semiconductor element 5 and the first bonding wires 7, so that an insulating resin having a filling viscosity of 1 Pa·s or more and less than 1000 Pa·s is used to assure a good filling property into the spaces. If the first insulating resin 11 has a filling viscosity of 1000 Pa·s or more, the filling property into the spaces between the first semiconductor element 5 and the first bonding wires 7 becomes low, and a non-filled portion is apt to generate. The filling viscosity of the first insulating resin 11 is desirably 500 Pa·s or below in order to enhance the filling property. Meanwhile, if the filling viscosity of the first insulating resin 11 is less than 1 Pa·s, it is excessively soft, and there is a possibility that a non-filled portion occurs or oozing (bleed) to the periphery might occur. It is more desirable that the first insulating resin 11 has a filling viscosity in a range of 10 to 50 Pa·s.

For the first insulating resin 11 having the above-described filling viscosity, a thermosetting resin such as an epoxy resin, a silicone resin or the like is used. The filling viscosity may be adjusted by adjusting the composition of the thermosetting resin configuring the first insulating resin 11 or by adjusting the temperature (e.g., heating temperature) of the first semiconductor element 5 in the filling step. The first insulating resin 11 of the thermosetting resin filled in the above-described spaces may be cured by thermally treating before the adhering step of the second semiconductor element 8 or may be cured at the same time when the second adhesive layer 9 for adhering the second semiconductor element 8 is subjected to a curing process.

For the second adhesive layer 9 excepting the portions where the first insulating resin 11 is filled, the second insulating resin having an adhering viscosity of 1 kPa·s or more and 100 kPa·s or less is used so as to maintain a layer shape which is to be the arrangement region for the first bonding wires 7. If the adhering viscosity of the second insulating resin exceeds 100 kPa·s, it is excessively hard, so that the first bonding wires 7 cannot be taken into the layer finely. Therefore, there is a possibility that the first bonding wires 7 are crushed. Meanwhile, if the adhering viscosity of the second insulating resin is less than 1 kPa·s, it is excessively soft, so that there is a possibility that the first bonding wires 7 come into contact with the second semiconductor element 8 or the resin bleeds from the element end faces. The adhering viscosity of the second insulating resin is more preferably in a range of 1 to 50 kPa·s, and most desirably in a range of 1 to 20 kPa·s.

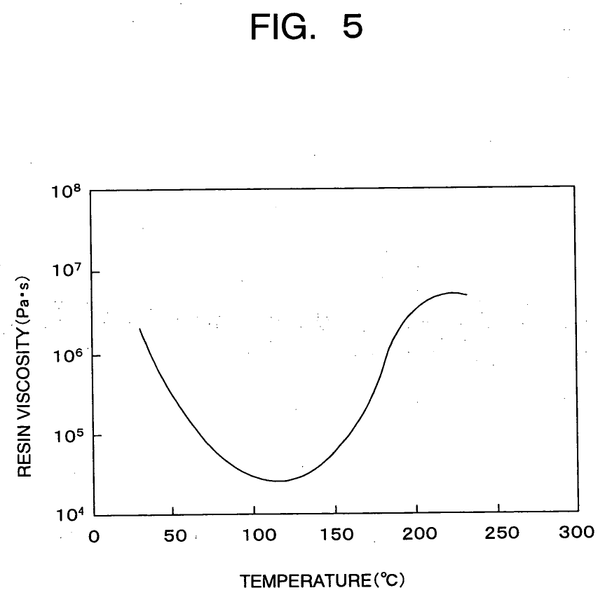

For the second insulating resin mainly configuring the second adhesive layer 9, for example, a thermosetting resin such as epoxy resin is used. The adhering viscosity of the thermosetting resin may be adjusted by adjusting the composition of the thermosetting resin or the like or can be adjusted by the heating temperature in the adhering step. FIG. 5 shows an example of the viscosity characteristic of the die attach material which is formed of epoxy resin. The die attach material having the viscosity characteristic shown in FIG. 5 can be set to have an adhering viscosity of 100 kPa·s or less by adjusting the adhering temperature to a range of approximately 70 to 160° C. And, the adhering viscosity can be set to 50 kPa·s or less by adjusting the adhering temperature to a range of approximately 90 to 140° C.

At the time of forming the second adhesive layer 9 of the second insulating resin, the second adhesive layer (second insulating resin layer) 9 having an appropriate viscosity with respect to the heating temperature in the adhering step can be obtained by appropriately adjusting, for example, a drying temperature of thermosetting resin composition. Here, the drying temperature indicates a temperature for setting, for example, the resin coating to a semi-cured state (B stage state) after the thermosetting resin composition is coated on the back surface of the second semiconductor element 8. The thermosetting resin layer in the semi-cured state can be softened or melted by heating to the semi-curing temperature (drying temperature) or more, so that a desired adhering viscosity can be obtained by appropriately adjusting the drying temperature and the heating temperature for adhering.

The first insulating resin 11 and the second insulating resin layer 9 configure the resin layer which is used to adhere the first semiconductor element 5 and the second semiconductor element 8 and also to seal the semiconductor elements 5 and 8. As described above, the resin having a high viscosity is used for the second insulating resin which mainly configures the second adhesive layer 9, and the resin having a low viscosity is used for the first insulating resin 11. Based on the difference in viscosity characteristic before the curing of the insulating resin, the second adhesive layer 9 is formed of two types of insulating resins having a different modulus of elasticity. In other words, the first insulating resin 11 has a low modulus of elasticity based on the low viscosity characteristic before curing. Meanwhile, the second insulating resin 9 has a high modulus of elasticity (a modulus of elasticity higher than that of the first insulating resin 11) based on the high viscosity characteristic before curing.

As described above, the second adhesive layer 9 is formed of two types of insulating resins having a different modulus of elasticity, so that the occurrence of bubbles due to the resin non-filled portions below the wires is prevented, and the second adhesive layer 9 which also serves as the sealing resin layer can be finely provided with a function of keeping the spaces between the first and second semiconductor elements 5 and 8. Here, the two types of insulating resins having a different modulus of elasticity may be any insulating resins having the same material if they have a different modulus of elasticity after curing.

And, the first and second semiconductor elements 5 and 8 which are stacked and disposed on the circuit board 2 are sealed with a sealing resin 13 such as epoxy resin to configure the semiconductor device 1 having a stacked multichip package structure. The structure that the two semiconductor elements 5, 8 were stacked was described with reference to FIG. 1 but the number of stacked semiconductor elements is not limited to it, and it is needless to say that three or more of them may be stacked. Where the semiconductor device is configured by stacking three or more semiconductor elements, an insulating resin having a low viscosity is previously filled in the lower spaces of the bonding wires present between the semiconductor elements.

For example, the semiconductor device 1 of the above-described embodiment is produced as follows. First, the first adhesive layer 6 is used to adhere the first semiconductor element 5 onto the circuit board 2. Subsequently, wire bonding is performed to electrically connect the electrode portions 4 of the circuit board 2 and the electrode pads of the first semiconductor element 5 by the first bonding wires 7. Then, the first insulating resin 11 having a filling viscosity in a range of 1 Pa·s or more and less than 1000 Pa·s is filled in the spaces between the first semiconductor element 5 and the first bonding wires 7. The first insulating resin 11 may be filled in the individual spaces by potting as described above or may be filled to entirely connect the spaces by printing. The first insulating resin 11 is subjected to a curing process as required.

Then, the circuit board 2 to which the first semiconductor element 5 is adhered is positioned on a heating stage. Meanwhile, the second semiconductor element 8 which has the second adhesive layer (second insulating resin layer) 9 formed on its bottom surface is held by a mounting tool. The mounting tool is provided with, for example, an adsorption holding means and a heating mechanism for the semiconductor element 8. The second semiconductor element 8 held by the mounting tool is aligned with the first semiconductor element 5 and lowered, and the second adhesive layer 9 is pressed against the first semiconductor element 5. At that time, at least either of the heating stage and the mounting tool is used to heat the second adhesive layer (second insulating resin layer) 9 so as to adjust its viscosity to a range of 1 to 100 kPa·s. The heating mode can be selected appropriately considering the adhering viscosity, the adhering velocity and the like of the second adhesive layer 9.

The second adhesive layer (second insulating resin layer) 9 has a function of keeping the space between the first and second semiconductor elements 5 and 8 according to the adhering viscosity, so that the first bonding wires 7 and the second semiconductor element 8 can be prevented from contacting with each other. In this state, the second adhesive layer (second insulating resin layer) 9 is cured to prevent the occurrence of a resin non-filled portion in the spaces below the first bonding wires 7 and also to retard more effectively the occurrence of an insulation failure, a short circuit or the like due to the contact between the first bonding wires 7 and the second semiconductor element 8. Thus, the semiconductor device 1 having a stacked multichip package structure of which reliability, operation property and the like are further improved can be realized.

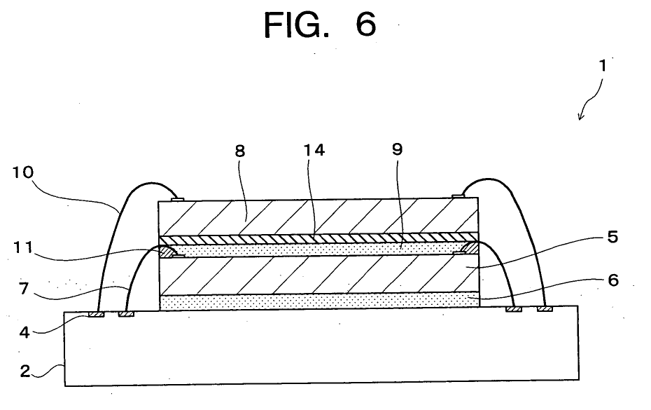

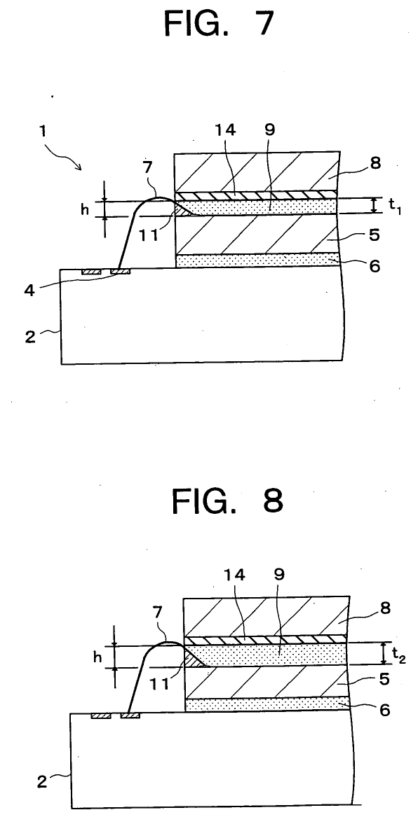

The semiconductor device 1 of the above-described embodiment retards the first bonding wires 7 and the second semiconductor element 8 from contacting with each other by the second adhesive layer 9 having an adhering viscosity in a range of 1 to 100 kPa·s. In addition, an insulating layer 14 may be formed on the bottom surface of the second semiconductor element 8, namely on the adhered surface (stacked surface) with the first semiconductor element 5 as shown in, for example, FIG. 6. The occurrence of an insulation failure, a short circuit or the like involved in the contact between the first bonding wires 7 and the second semiconductor element 8 can be prevented surely by disposing the insulating layer 14 on the bottom surface of the second semiconductor element 8. For the insulating layer 14, an insulating resin or the like having a heat resistance against the adhering temperature is used.

Where the insulating layer 14 is disposed on the bottom surface of the second semiconductor element 8, the first bonding wires 7 are positively contacted to the insulating layer 14 as shown in, for example, FIG. 7. Thus, the first bonding wires 7 may be deformed toward the circuit board 2. In other words, the insulating layer 14 can be used not only to prevent a short circuit or the like involved in the contact between the first bonding wires 7 and the second semiconductor element 8 but also as a layer for positively deforming the first bonding wires 7 toward the circuit board 2. Thus, the insulating layer 14 can be used to deform the first bonding wires 7 toward the circuit board 2 so as to realize further thinning of the semiconductor device 1.

Here, the thinning of the semiconductor device 1 based on the deformation of the first bonding wires 7 will be described with reference to FIG. 7 and FIG. 8. FIG. 7 is a view showing an example that the first bonding wires 7 are positively deformed by contacting to the insulating layer 14. FIG. 8 is a view showing an example that the first bonding wires 7 are not contacted to the insulating layer 14. It is assumed that the first bonding wires 7 just above the first semiconductor element 5 have a maximum height h in a tolerance of 60±15 μm. As shown in FIG. 8, when the insulating layer 14 does not have but only a function of preventing the occurrence of an insulation failure, a short circuit or the like, it is necessary to set a thickness t₂ of the second adhesive layer 9 to the upper limit value (60+15=75 μm) in the tolerance (60±15 μm) of the wire height h.

Meanwhile, it is seen in FIG. 7 that bonding wires, which have a height exceeding a standard value 60 μm of the wire height h, are contacted to the insulating layer 14 which is disposed on the bottom surface of the second semiconductor element 8 so as to be deformed toward the circuit board 2. In other words, a thickness t₁ of the second adhesive layer 9 is set to the standard value 60 μm of the wire height h, so that the real wire height h falls in a range of 60-15 μm (45 to 60 μm). Thus, at least some (in this case, the bonding wires which exceed the standard value of the wire height h) of the plural wires configuring the first bonding wires 7 are positively contacted to the insulating layer 14 so as to be deformed, so that the thickness t₁ of the second adhesive layer 9 can be set without depending on the tolerance of the wire height h. Therefore, the thickness of the semiconductor device 1 can be made thinner in comparison with the device structure shown in FIG. 8.

The configuration that the thickness t₁ of the second adhesive layer 9 is set to the standard value (60 μm) of the wire height h is merely one example, and the thickness t₁ of the second adhesive layer 9 is not limited to it. The thickness t₁ of the second adhesive layer 9 can be appropriately set in a range of the standard value (60 μm) or less of the wire height h. For example, it is also possible to set to the lower limit value (60−15=45 μm) in the tolerance (60±15 μm) of the wire height h. By configuring in this way, the real wire height h becomes constant at 45 μm, and the semiconductor device 1 can be made thinner. The thickness t₁ of the second adhesive layer 9 can also be set to the lower limit value or less of the wire height h. In this case, the degree of deformation of the bonding wires 7 increases, and a connection failure or the like is apt to occur. Therefore, the thickness t₁ of the second adhesive layer 9 is preferably set within the tolerance of the wire height h.

The insulating layer 14 which is disposed on the bottom surface of the second semiconductor element 8 is formed of an insulating resin which has, for example, a heat resistance to the adhering temperature of the second adhesive layer 9 and a strength capable of deforming the first bonding wires 7. Its specific material is not particularly limited. Examples of specific constituent material for the insulating layer 14 include polyimide resin, silicone resin, epoxy resin, acrylic resin and other thermosetting resins. The insulating layer 14 formed of such an insulating resin can be formed by, for example, adhering a resin film, coating and curing a resin composition, or the like. Where the insulating layer 14 is formed by applying the resin film, a film having a two-layer structure which has the second insulating resin layer to be the second adhesive layer 9 formed can also be used for the resin film configuring the insulating layer 14.

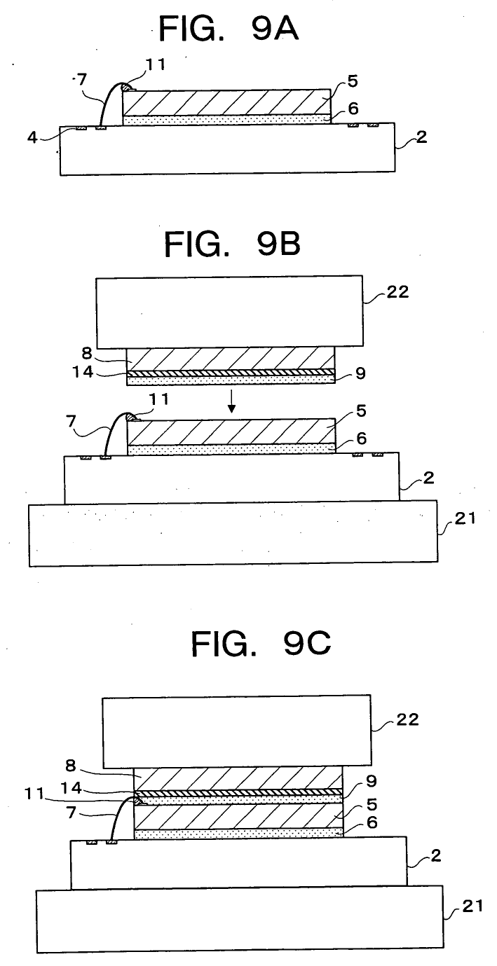

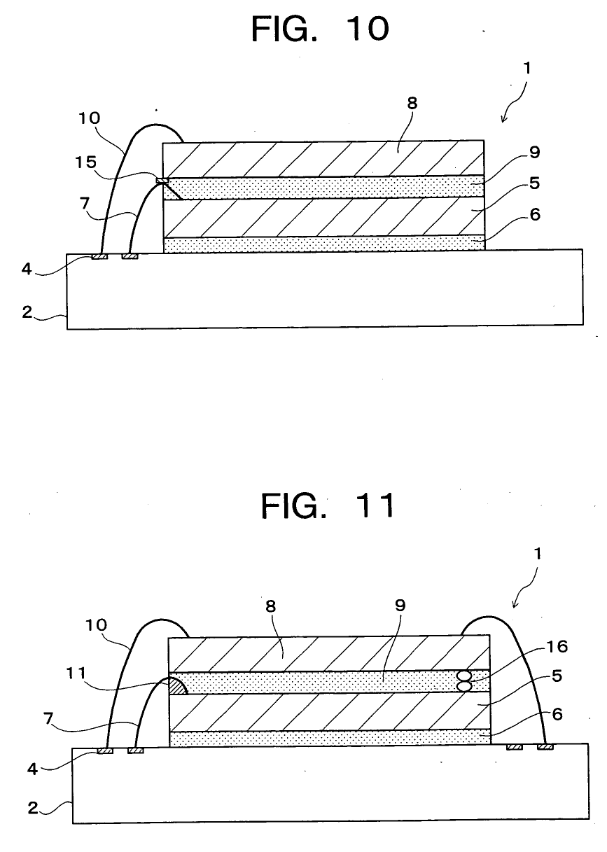

For example, the semiconductor device 1 shown in FIG. 7 is manufactured as follows. First, as shown in FIG. 9A, the first semiconductor element 5 is adhered onto the circuit board 2 by using the first adhesive layer 6. Then, wire bonding is performed to electrically connect the electrode portions 4 of the circuit board 2 and the electrode pads of the first semiconductor element 5 by the first bonding wires 7. Then, the first insulating resin 11 is filled in the spaces between the first bonding wires 7 and the first semiconductor element 5. The first insulating resin 11 is filled in the same way as described above.

Then, the circuit board 2 on which the first semiconductor element 5 is mounted by adhering is placed on a heating stage 21 as shown in FIG. 9B. Meanwhile, the second semiconductor element 8 which has the insulating layer 14 and the second adhesive layer 9 sequentially formed on its bottom surface is held by a mounting tool 22. The mounting tool 22 is provided with, for example, an adsorption holding means and a heating mechanism for the semiconductor element 8. Then, the second semiconductor element 8 held by the mounting tool 22 is aligned with the first semiconductor element 5 and lowered to press the second adhesive layer 9 against the first semiconductor element 5. At this time, the second adhesive layer 9 is heated by at least either of the heating stage 21 and the mounting tool 22 to adjust its viscosity to a range of 1 to 100 kPa·s. The second adhesive layer 9 is set to a thickness which is, for example, equal to or less than the standard value of the wire height h.

Where the second adhesive layer 9 is set its thickness to the standard value of the wire height h, the first bonding wires 7 having a height on the plus side with respect to the standard value are contacted to the insulating layer 14 to deform toward the circuit board 2 in the process of pressing the second adhesive layer 9 against the first semiconductor element 5 (FIG. 9C). A pressing force (load) of the second semiconductor element 8 against the first semiconductor element 5 by the mounting tool 22 is set appropriately considering ductility of the first bonding wires 7, the number of wires deformed and the like. For example, when it is assumed that a load of 7 g is necessary to deform a bonding wire having a diameter of 25 μm by 10 μm, the load at the time of adhering is desired to be approximately [(Load required for deforming (e.g., 7 g))×(number of wires)×1.2 times)]. In this state, the second adhesive layer 9 is cured by, for example, heating.

As described above, in the process of pressing the second adhesive layer 9 against the first semiconductor element 5, the first bonding wires 7 are partly contacted to the insulating layer 14 and deformed toward the circuit board 2, so that each of the first bonding wires 7 can be set to have a height of the standard value or less of the wire height h. In other words, the first bonding wires 7 have a height equal to or less than the thickness of the second adhesive layer 9, so that the semiconductor device 1 as a whole can be made thinner depending on the thickness of the second adhesive layer 9. And, the insulation between the first bonding wires 7 and the second semiconductor element 8 is maintained by the insulating layer 14, so that there is no possibility of an insulation failure, a short circuit or the like. Thus, the semiconductor device 1 which has the stacked multichip package structure having achieved both further thinning and improvement of reliability can be realized.

The occurrence of an insulation failure, a short circuit or the like due to the contact between the first bonding wires 7 and the second semiconductor element 8 can also be prevented by the insulating coated layer 15 which is disposed on the outer circumferential surface of the first bonding wires 7 as shown in FIG. 10. For example, the insulating coated layer 15 can be formed by applying a thermosetting insulating resin or the like to the contact portion between the first bonding wires 7 and the second semiconductor element 8 by blowing, dripping or the like, and curing the coated layer of the insulating resin.

Besides, the first bonding wires 7 can be at least partly contacted to the second semiconductor element 8 via the insulating coated layer 15 to deform toward the circuit board 2 by adding a load based on the contact with the second semiconductor element 8. The degree of deformation of the first bonding wires 7 and the wire height based on it are same as in the case of applying the insulating layer 14. By configuring in this way, the first bonding wires 7 can be aligned to have a height of a prescribed value (e.g., the value in a range of the standard value to the lower limit value of the wire height h) or below. Therefore, the semiconductor device 1 as a whole can be made much thinner.

As shown in FIG. 11, the distance between the first semiconductor element 5 and the second semiconductor element 8 may be maintained by forming a stud bump 16 formed of a metal material, a resin material or the like on the electrode pad not used for the connection of the first semiconductor element 5, namely non-connection pad. The stud bump 16 function effectively to retard an insulation failure, a short circuit or the like involved in the contact between the first bonding wires 7 and the second semiconductor element 8. The stud bump 16 may be disposed at one region but preferably disposed at three regions or more which cross the center of gravity of the first semiconductor element 5.

The non-connection pad causes bubbles. The stud bump 16 formed on the non-connection pad demonstrates an effect also to prevent the occurrence of bubbles. When the first insulating resin 11 is filled in the spaces between the first semiconductor element 5 and the first bonding wires 7, the non-connection pad may be filled by the first insulating resin 11. The occurrence of bubbles can be prevented also by this. Besides, when fuse parts exist on the surface of the semiconductor element, the fuse parts cause bubbles, too. The fuse parts may be filled by the first insulating resin 11. The fuse parts are smaller than the connection pads. It is desirable to fill in the fuse parts with the first insulating resin 11 by applying a jet system.

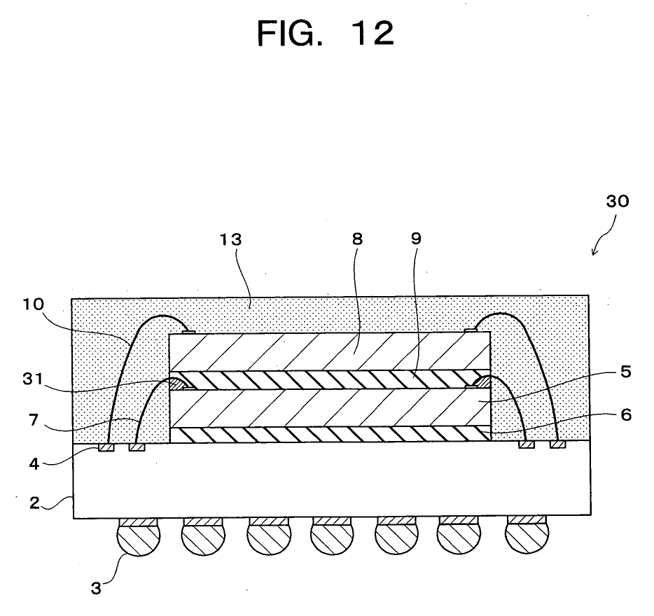

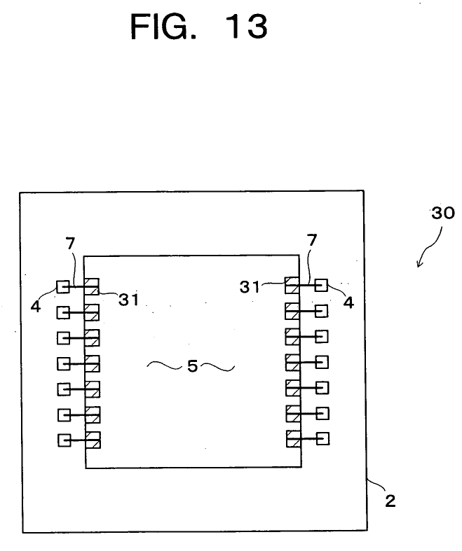

Then, a second embodiment of the present invention will be described with reference to FIG. 12 and FIG. 13. It is to be understood that the same reference numerals are allotted to the same elements as those in the above-described first embodiment, and the description thereof is partly omitted. A semiconductor device 30 shown in FIG. 12 has the first semiconductor element 5 adhered onto the circuit board 2 via the first adhesive layer 6 in the same manner as in the above-described first embodiment. The electrode pads of the first semiconductor element 5 are electrically connected to the electrode portions 4 of the circuit board 2 via the first bonding wires 7. The second semiconductor element 8 is adhered onto the first semiconductor element 5 via the second adhesive layer 9 which is formed of a thermosetting insulating resin having an adhering viscosity of 1 kPa·s or more and 100 kPa·s or less. The second adhesive layer 9 is the same as the second insulating resin of the first embodiment.

For example, a photo-setting insulating resin 31 such as an ultraviolet-setting type insulating resin is filled and cured in the spaces between the first semiconductor element 5 and the first bonding wires 7. The photo-setting insulating resin 31 filled and cured is, for example, an ultraviolet-setting type acrylic resin composition. The ultraviolet-setting type acrylic resin composition contains prepolymer or monomer having an acryloyl group as a reaction group and a photopolymerization initiator and is cured by ultraviolet irradiation. The ultraviolet-setting type acrylic resin composition or the like is cured only the portions exposed to the irradiation of ultraviolet rays, so that the shape after coating can be stabilized with ease.

After the first bonding wires 7 are bonded to the electrode pads of the first semiconductor element 5, the photo-setting insulating resin 31 is filled in the spaces between the first semiconductor element 5 and the first bonding wires 7 and cured by irradiating light such as ultraviolet rays prior to the step of adhering the second semiconductor element 8. For example, it is desirable that the photo-setting insulating resin 31 is filled in each space between the first semiconductor element 5 and the first bonding wires 7 and cured by irradiating desired light such as ultraviolet rays as shown in FIG. 13.

Thus, by previously filling to cure the photo-setting insulating resin 31 in the spaces between the first semiconductor element 5 and the first bonding wires 7, the occurrence of bubbles due to the resin non-filled portions below the wires can be prevented without fail. Besides, it is not necessary to worry the occurrence of the resin non-filled portions below the wires, so that an adhesive agent resin having a high viscosity which can keep its shape (predetermined layer thickness or the like) can be applied to the second adhesive layer 9. Thus, it becomes possible to provide the second adhesive layer 9 with a function of keeping the space between the first and second semiconductor elements 5 and 8 satisfactorily. Thus, the semiconductor device 30 having a stacked multichip package structure with its reliability, operation property and the like improved can be realized.

The second adhesive layer 9 formed of the thermosetting insulating resin and the photo-setting insulating resin 31 have a different modulus of elasticity depending on a difference in their cured states. Where the photo-setting insulating resin 21 is filled in the spaces between the first semiconductor element 5 and the first bonding wires 7, the adhesive layer (resin sealing layer) can be formed of two types of insulating resins having a different modulus of elasticity. Using the resin layer formed of two types of insulating resins having a different modulus of elasticity, the occurrence of resin non-filled portions below the wires is prevented, and the occurrence of an insulation failure, a short circuit or the like due to the contact between the first bonding wires 7 and the second semiconductor element 8 can be retarded effectively.

In the same manner as in the first embodiment, the semiconductor device 30 according to the second embodiment can also form the insulating layer on the back surface of the second semiconductor element 8 and form an insulating coated layer on the outer circumferential surfaces of the first bonding wires 7. Besides, it is also effective to deform the first bonding wires 7 toward the circuit board 2 by using the insulating layer and the insulating coated layer. And, the distance between the first semiconductor element 5 and the second semiconductor element 8 may be kept by stud bumps. The stud bumps are effective to retard an insulation failure, a short circuit or the like involved in the contact between the first bonding wires 7 and the second semiconductor element 8.

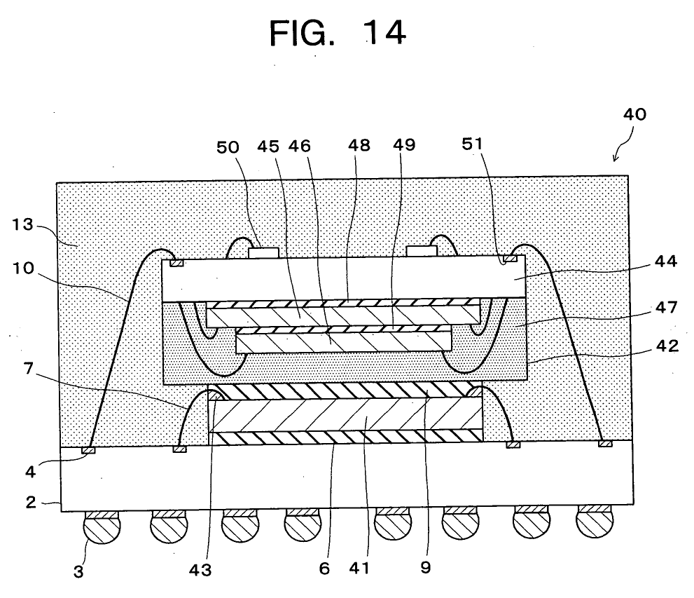

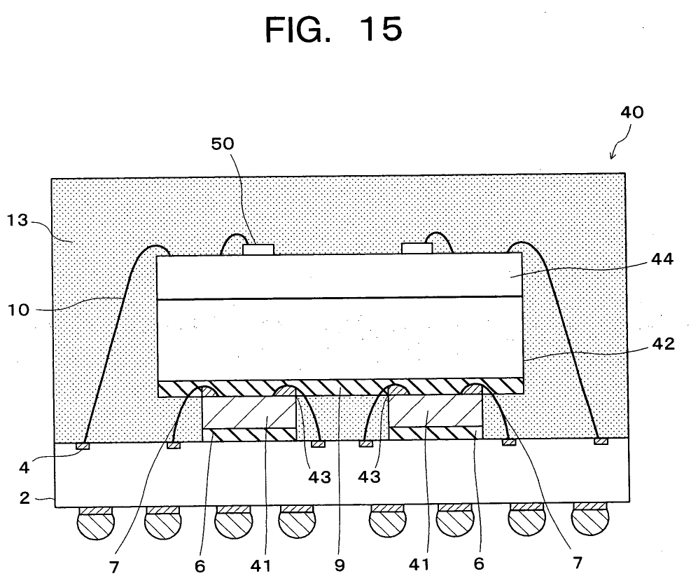

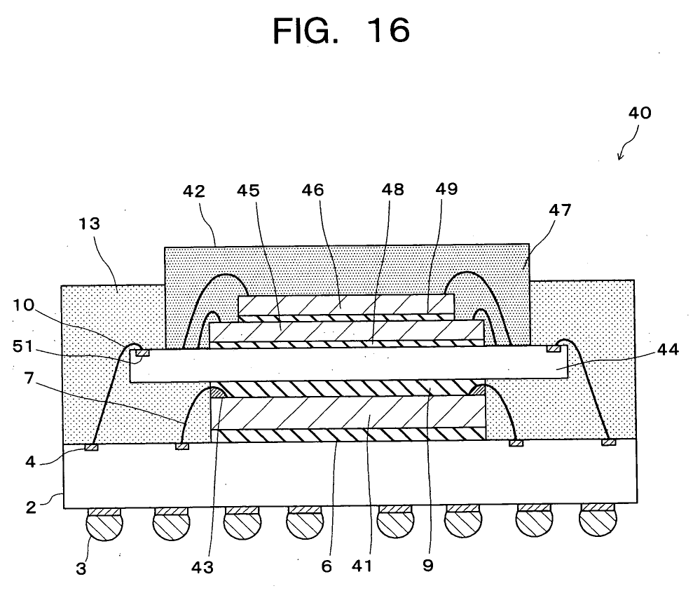

Then, a third embodiment of the present invention will be described with reference to FIG. 14, FIG. 15 and FIG. 16. FIG. 14 is a sectional view schematically showing a structure of the third embodiment that the stacked electronic part of the present invention is applied to a semiconductor device. It is to be understood that the same reference numerals are allotted to the same elements as those of the above-described first and second embodiments and the description thereof is omitted partly. A semiconductor device 40 shown in FIG. 14 has a semiconductor element 41 as a first electronic part and a package part 42 as a second electronic part stacked to configure a stacked package structure. Thus, the electronic parts configuring the stacked electronic part are not limited to a semiconductor element alone (bear chip) but may be a part which has a semiconductor element packaged previously. Besides, the electronic parts may be those such as general circuit parts other than the semiconductor parts such as the semiconductor element 41, the package part 42 and the like.

The semiconductor device 40 shown in FIG. 14 has the semiconductor element 41 as the first electronic part adhered onto the circuit board 2 via the first adhesive layer 6 in the same manner as in the above-described embodiment. The electrode pads of the semiconductor element 41 are electrically connected to the electrode portions 4 of the circuit board 2 via the first bonding wires 7. The package part 42 as the second electronic part is adhered onto the semiconductor element 41 via the second adhesive layer 9 which is formed of an insulating resin having an adhering viscosity of 1 kPa·s or more and 100 kPa·s or below. An insulating resin 43 formed of the insulating resin (first embodiment) having a filling viscosity of 1 Pa·s or more and less than 1000 Pa·s or the photo-setting insulating resin (second embodiment) is filled in the spaces between the semiconductor element 41 and the first bonding wires 7.

The package part 42 has a structure that a first semiconductor element 45 and a second semiconductor element 46 are sequentially stacked on a circuit board 44 and is previously packaged with a sealing resin 47. The first semiconductor element 45 is adhered onto the circuit board 44 via an adhesive agent layer 48, and the second semiconductor element 46 is similarly adhered onto the first semiconductor element 45 via an adhesive agent layer 49. Reference numeral 50 denotes a passive part. The package part 42 is stacked on the semiconductor element 41 such that the circuit board 44 is positioned upward. Besides, electrode pads 51 which are disposed on the back surface of the circuit board 44 are electrically connected to the electrode portions 4 of the circuit board 2 via the second bonding wires 10.

And, the semiconductor element 41 and the package part 42 disposed by stacking on the circuit board 2 are sealed by using, for example, the sealing resin 13 such as epoxy resin to configure the semiconductor device 40 having a stacked package structure. This semiconductor device 40 can prevent the occurrence of a resin non-filled portion in the spaces below the first bonding wires 7. Besides, the first bonding wires 7 can be retarded from having a defective connection or the like resulting from excessive contact of the first bonding wires 7 and the package part 42. Thus, the semiconductor device 40 having reliability, operation property and the like improved furthermore can be realized.

The stacked structure of the semiconductor element 41 and the package part 42 may have the package part 42 stacked on the two semiconductor elements 41, 41 which are disposed on the circuit board 2 as shown in, for example, FIG. 15. This stacked structure is effective when the semiconductor element 41 has a size which is largely different from that of the package part 42. The package part 42 can also be stacked with the circuit board 44 disposed below as shown in FIG. 16. In this case, the second bonding wires 10 are connected to the electrode pads 51 which are disposed on the top surface of the circuit board 44. The third embodiment can also be modified in various ways similar to the first and second embodiments.

The present invention is not limited to the above-described embodiments and can also be applied to various types of stacked electronic parts which have plural electronic parts mounted by stacking. Such stacked electronic parts are also included in the present invention. The embodiments of the present invention can be expanded or modified within the scope of technical idea of the present invention, and the expanded and/or modified embodiments are also included in the technical scope of the present invention.

1. A stacked electronic part, comprising:
a substrate having electrode portions;
a first electronic part having first electrode pads which are connected to the electrode portions via first bonding wires and bonded on the substrate via a first adhesive layer; and
a second electronic part having second electrode pads which are connected to the electrode portions via second bonding wires and bonded on the first electronic part via a second adhesive layer,
wherein the second adhesive layer has a first insulating resin, which is filled in the spaces between the first electronic part and the first bonding wires, and a second insulating resin, which is disposed to adhere the first electronic part and the second electronic part and has a modulus of elasticity different from that of the first insulating resin.

2. A stacked electronic part according to claim 1,
wherein the second insulating resin has the modulus of elasticity higher than that of the first insulating resin.

3. A stacked electronic part according to claim 1, wherein the second electronic part has a shape equal to or larger than that of the first electronic part.

4. A stacked electronic part according to claim 1,
wherein the first and second electronic parts comprise at least one selected from a semiconductor element and a package part including a semiconductor element.

5. A stacked electronic part according to claim 1,
wherein an insulating layer is disposed on an adhesion surface of the second electronic part with the first electronic part.

6. A stacked electronic part according to claim 5,
wherein the first bonding wires are contacted to the insulating layer which is disposed on the second electronic part and deformed toward the substrate.

7. A stacked electronic part according to claim 1,
wherein the first bonding wires have an insulating coated layer which is disposed on their outer circumferential surfaces and are contacted to the second electronic part via the insulating coated layer to deform toward the substrate.

8. A stacked electronic part according to claim 1,
wherein a stud bump which is disposed on a non-connected pad of the first electronic part is arranged between the first electronic part and the second electronic part.

9. A stacked electronic part according to claim 1,
wherein the first and second electronic parts are sealed with a sealing resin.

10. A stacked electronic part, comprising:
a substrate having electrode portions;
a first electronic part having first electrode pads which are connected to the electrode portions via first bonding wires and bonded on the substrate via a first adhesive layer; and
a second electronic part having second electrode pads which are connected to the electrode portions via second bonding wires and bonded on the first electronic part via a second adhesive layer,
wherein the second adhesive layer has a first insulating resin, which is filled in the spaces between the first electronic part and the first bonding wires and has a filling viscosity in a range of 1 Pa·s or more and less than 1000 Pa·s, and a second insulating resin, which is disposed to adhere the first electronic part and the second electronic part and has an adhering viscosity in a range of 1 kPa·s or more and 100 kP·s or less.

11. A stacked electronic part according to claim 10,
wherein the second insulating resin has the modulus of elasticity different from that of the first insulating resin.

12. A stacked electronic part according to claim 10,
wherein the second electronic part has a shape equal to or larger than that of the first electronic part.

13. A stacked electronic part according to claim 10,
wherein the first and second electronic parts comprise at least one selected from a semiconductor element and a package part including a semiconductor element.

14. A stacked electronic part according to claim 10,
wherein an insulating layer is disposed on an adhesion surface of the second electronic part with the first electronic part.

15. A stacked electronic part, comprising:
a substrate having electrode portions;
a first electronic part having first electrode pads which are connected to the electrode portions via first bonding wires and bonded on the substrate via a first adhesive layer; and
a second electronic part having second electrode pads which are connected to the electrode portions via second bonding wires and bonded on the first electronic part via a second adhesive layer,
wherein the second adhesive layer has a photo-setting insulating resin, which is filled in the spaces between the first electronic part and the first bonding wires, and a thermosetting insulating resin, which is disposed to adhere the first electronic part and the second electronic part and has an adhering viscosity in a range of 1 kPa·s or more and 100 kPa·s or less.

16. A stacked electronic part according to claim 15,
wherein the thermosetting insulating resin has a modulus of elasticity different from that of the photo-setting insulating resin.

17. A stacked electronic part according to claim 15,
wherein the second electronic part has a shape equal to or larger than that of the first electronic-part.

18. A stacked electronic part according to claim 15,
wherein the first and second electronic parts comprise at least one selected from a semiconductor element and a package part including a semiconductor element.

19. A stacked electronic part according to claim 15,
wherein an insulating layer is disposed on an adhesion surface of the second electronic part with the first electronic part.
